(19) United States
(12) Patent Application Publication
(10) Pub. No.: US 2008/0042263 A1
(43) Pub. Date: Feb. 21, 2008

(54) REINFORCED SEMICONDUCTOR PACKAGE AND STIFFENER THEREOF

(75) Inventors: Tong-hong Wang, Kaohsiung City (TW); Ching-chun Wang, Kaohsiung City (TW)

Correspondence Address: MADSON & AUSTIN, 15 WEST SOUTH TEMPLE, SUITE 900, SALT LAKE CITY, UT, 84101, US

(73) Assignee: Advanced Semiconductor Engineering, Inc., Kaohsiung City (TW)

(21) Appl. No.: 11/838,804

(22) Filed: Aug. 14, 2007

(30) Foreign Application Priority Data
Aug. 21, 2006 (TW) 095130568

(51) Int. Cl. H01L 23/36; H01L 23/02

(52) U.S. Cl. 257/712; 257/729; 257/E23.18; 257/E23.101

(57) ABSTRACT

A reinforced semiconductor package (500, 700) with a stiffener (400, 600) is provided. The stiffener is composed of an inner ring (410) disposed on the upper surface (512) of a substrate (510) and surrounding a semiconductor chip (520), and an outer ring (420) also disposed on the upper surface of the substrate but surrounding the inner ring. The inner ring and the outer ring are connected with each other by means of at least one tie bar (430), and cooperatively cover a majority portion of the upper surface of the substrate. Accordingly, the strength and rigidity of the substrate of the present semiconductor package can be reinforced to efficiently prevent warpage thereof.

### BACKGROUND OF THE INVENTION

1. Field of the Invention

The present invention relates to a semiconductor package, and particularly to a reinforced semiconductor package with a stiffener.

2. Description of Prior Art

High-performance Flip Chip BGA (HFCBGA) packages are generally reinforced in structure by adopting a metal ring that supports a heat sink at the top of the package. The structure of a conventional HFCBGA package is illustrated in FIG. 1 of the attached drawings. As shown, the conventional HFCBGA package 100 includes a substrate 102, a semiconductor (or integrated circuit) chip 104 disposed on a central area of the upper surface 108 of the substrate 102, a metal ring 106 disposed on the outer perimeter of the upper surface 108 of the substrate 102 and surrounding the semiconductor chip 104, and a heat sink 116 resting on upper surfaces of the semiconductor chip 104 and the metal ring 106. In general, the chip 104 is electrically connected to the substrate 102 by means of a plurality of bumps 110 that are encapsulated by an underfill 112. A plurality of solder balls 114 is further attached to the bottom of the substrate 102 for electrically connecting the package 100 to an external device.

It is well known that, during the process of fabrication, the above-discussed package 100 must be subjected to high temperature conditions for several times, including solder reflowing, underfill material dispensing and solder ball mounting processes. This would easily cause warpage of the entire package structure 100 or even cracking of the chip 104, making the resulted package product degraded in quality and reliability. When a flexible or thin substrate 102 is used as the base, the package warpage would be even worse. In this case, the metal ring 106 provided on the substrate 102, acting as a stiffener, will help strengthen the rigidity of the substrate 102. Therefore, due to the provision of the metal ring 106, the above package structure would be less likely subject to a large amount of warpage.

The disadvantage of the above conventional package 100, however, is that the substrate 102 still has the tendency to warp since the metal ring 106 is only disposed on the outer perimeter of the upper surface 108 of the substrate 102. When the amount of substrate warpage reaches a limit, separation or displacement of the metal ring 106 from the substrate 102 would occur.

One solution to the above problem is proposed in Taiwan Patent No. 1220306, which is illustrated in FIGS. 2A and 2B of the attached drawings. The Taiwan Patent discloses a semiconductor package 200, which adopts an improved metal ring 206 functioning both as a heat sink for heat dissipation and a stiffener for strengthening a substrate 202 of the package 200. The metal ring 206 is composed of an upper portion 206a disposed on an upper surface 208 of the substrate 202, and a side portion 206b downwardly extending from the upper portion 206a. The upper portion 206a defines a central opening 207 for receiving and exposing a semiconductor chip 204 bonded to the upper surface 208 of the substrate 202. The side portion 206b is in engagement with four side surfaces 202a, 202b, 202c, and 202d of the substrate 202.

As shown in FIGS. 3A-3C, which illustrate an alternative semiconductor package 300 proposed by the Taiwan Patent, which employs an octagonal metal ring 306. The octagonal metal ring 306 is composed of an upper portion 306a, a lower portion 306c, and a side portion 306b interconnecting the upper portion 306a with the lower portion 306c. The upper portion 306a is disposed on the upper surface 308 of a substrate 302 of the package 300, and also defines a central opening 307 for receiving and exposing a semiconductor chip 304 bonded to the upper surface 308 of the substrate 302. The lower portion 306c is disposed on the lower surface 314 of the substrate 302. The side portion 306b is in engagement with portions of four side surfaces 302a, 302b, 302c, and 302d of the substrate 302 with four corners 324a, 324b, 324c, and 324d of the substrate 302 outwardly exposed from the metal ring 306.

Although the metal ring 206, 306 of the above-described conventional semiconductor package 200, 300 is improved in structure so that the side portions of the substrate 202, 302 are also reinforced in strength, there still exists potential risk that warpage of the substrate 202, 302 may occur. This is because only a peripheral portion, not a majority portion, of the upper surface of the substrate 202, 302 is reinforced by the metal ring 206, 306. Such a substrate warpage would result in uneven interface planarity of the package 202, 302, thereby making surface mounting of the package 202, 302 difficult if not impossible. In worse, cracking of the semiconductor chip 204, 304 may even be caused.

Accordingly, it is desired to provide an improved reinforced semiconductor package that addresses the above problems encountered in the prior art.

### SUMMARY OF THE INVENTION

An objective of the present invention is to provide a reinforced semiconductor package and an improved stiffener thereof. The stiffener is improved in structure to efficiently prevent the substrate of the semiconductor package from warping, thereby ensuring reliability in surface mounting of the package and avoiding chip cracking.

To realize the above objective of the present invention, a reinforced semiconductor package in accordance with a first embodiment of the present invention comprises a substrate, a semiconductor chip bonded to an upper surface of the substrate, a heat sink and a stiffener. The stiffener is composed of an inner ring disposed on the upper surface of the substrate and surrounding the semiconductor chip, and an outer ring also disposed on the upper surface of the substrate but surrounding the inner ring. The inner ring and the outer ring are connected with each other by means of at least one tie bar, and cooperatively cover a majority portion of the upper surface of the substrate. The heat sink is positioned on coplanar upper surfaces of the semiconductor chip and the outer ring of the stiffener.

A reinforced semiconductor package in accordance with a second embodiment of the present invention is similar to that of the first embodiment, but with the stiffener thereof differently configured. The stiffener of the second embodiment further comprises, besides an inner ring and an outer ring similar to those of the first embodiment, a side portion connected with the outer ring and a lower portion connected with the side portion. The side portion of the stiffener is in engagement with side surfaces of the substrate, and the lower portion of the stiffener is in engagement with a lower surface of the substrate.

As described above, since a majority portion of the upper surface of the substrate is covered by inner and outer rings of the present stiffener, the strength and rigidity of the substrate of the present semiconductor package is thus sufficiently reinforced to prevent warpage thereof. The additional side portion and lower portion respectively covering side surfaces and the lower surface of the substrate, as provided in the second embodiment, further strengthen the strength of the substrate and thus substrate warpage is effectively eliminated.

### BRIEF DESCRIPTION OF THE DRAWINGS

The present invention may best be understood through the following description with reference to the accompanying drawings, in which:

FIG. 1 is a cross-sectional view of a conventional HFCBGA package having a metal ring for substrate reinforcement;

FIG. 2A is a top view of another conventional semiconductor package having a heat sink for protecting the edges of a substrate thereof;

FIG. 2B is a cross-sectional view taken along line 2B-2B of FIG. 2A;

FIG. 3A is a top view of a further conventional semiconductor package having a heat sink for protecting the edges of a substrate thereof;

FIG. 3B is a cross-sectional view taken along line 3B-3B of FIG. 3A;

FIG. 3C is a cross-sectional view taken along line 3C-3C of FIG. 3A;

FIG. 4A is a perspective view of a stiffener for a reinforced semiconductor package in accordance with a first embodiment of the present invention;

FIG. 4B is a top view of the stiffener of FIG. 4A;

FIG. 5 is a cross-sectional view of a reinforced semiconductor package embodying the stiffener shown in FIGS. 4A and 4B;

FIG. 6 is a cross-sectional view of a stiffener for a reinforced semiconductor package in accordance with a second embodiment of the present invention; and

FIG. 7 is a cross-sectional view of a reinforced semiconductor package embodying the stiffener shown in FIG. 6.

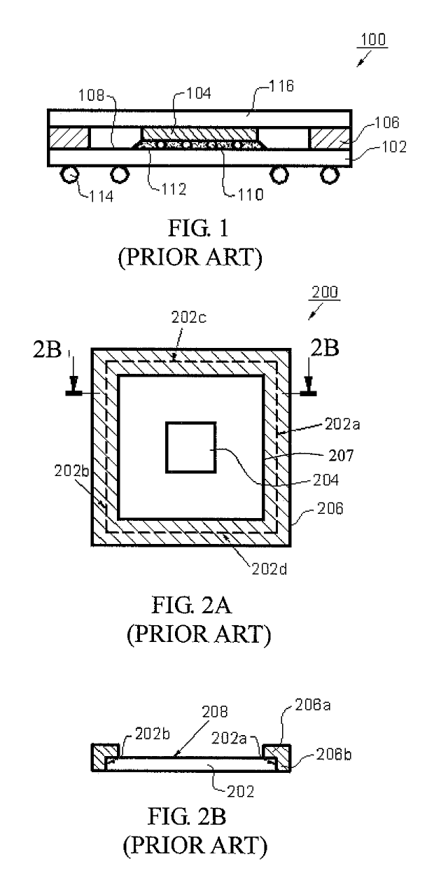

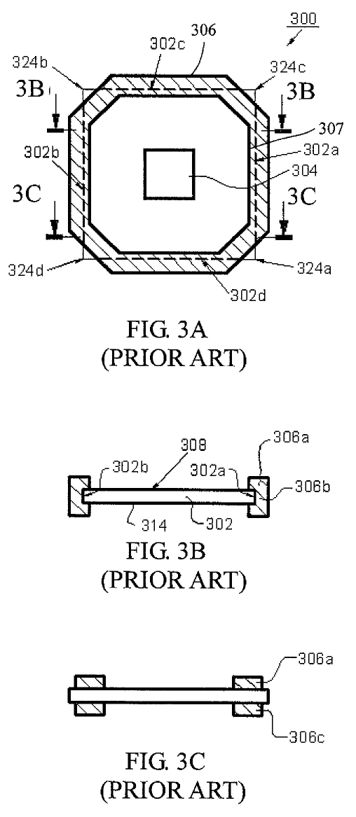

### DETAILED DESCRIPTION OF THE PREFERRED EMBODIMENTS

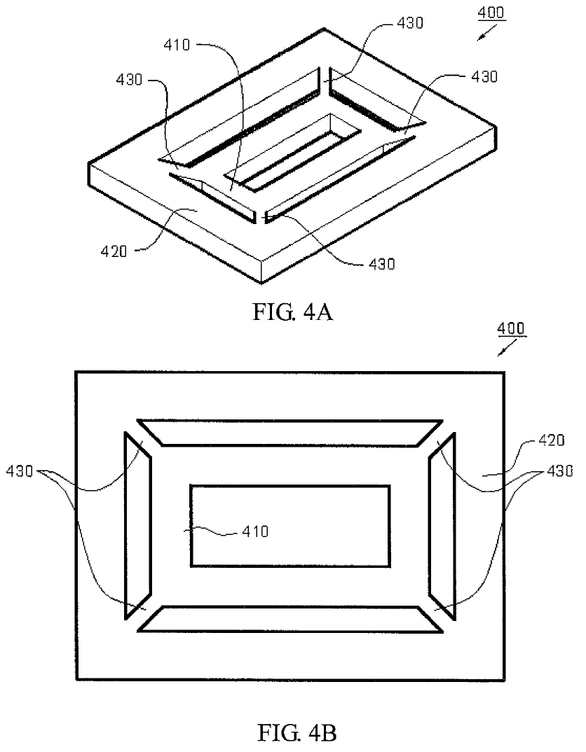

With reference to the drawings and in particular to FIGS. 4A and 4B, a stiffener, generally designated at 400, for a reinforced semiconductor package in accordance with a first embodiment of the present invention is shown. The stiffener 400 comprises an inner ring 410, an outer ring 420 surrounding the inner ring 410, and at least one tie bar 430 connecting the inner ring 410 with the outer ring 420 so as to maintain the relative position between the two rings 410, 420.

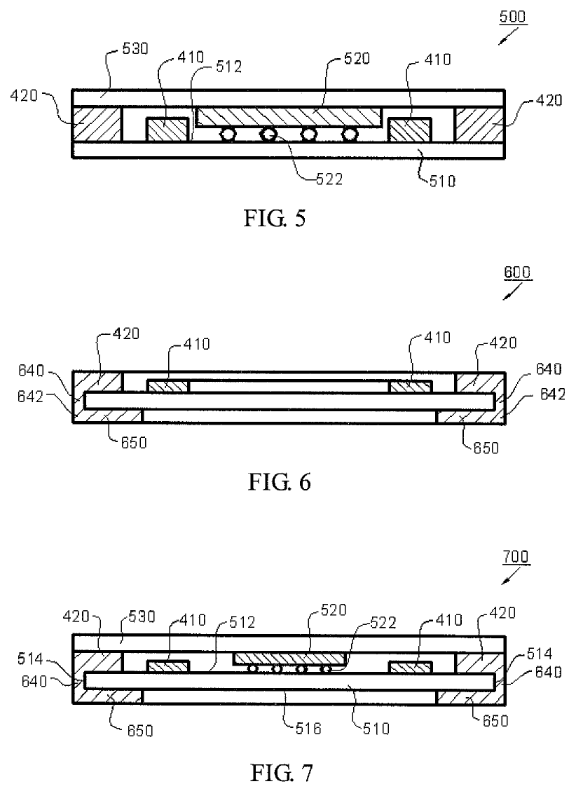

Also referring to FIG. 5, a reinforced semiconductor package 500 in accordance with the first embodiment of the present invention embodying the stiffener 400 shown in FIGS. 4A and 4B is illustrated in cross-sectional form. The reinforced semiconductor package 500 comprises a substrate 510, a semiconductor chip 520 bonded to an upper surface 512 of the substrate 510, the stiffener 400 and a heat sink 530. The semiconductor chip 520 is electrically connected with the substrate 510 via a plurality of bumps 522. Both the inner ring 410 and the outer ring 420 of the stiffener 400 are adhered to the upper surface 512 of the substrate 510. The inner ring 410 accommodates and surrounds the semiconductor chip 520. The heat sink 530 is positioned on the semiconductor chip 520 and is adhered to an upper surface of the outer ring 420 of the stiffener 400.

The inner ring 410 and the outer ring 420 of the stiffener 400 are generally rectangular in cross-section to conform to the shape of the substrate 510, but not necessary to be so. As shown in FIGS. 4A and 4B, to reliably maintain the relative position between the inner and outer rings 410, 420 of the stiffener 400, four tie bars 430 connecting the two rings 410, 420 are preferred. Further, as clearly shown in FIG. 5, the thickness of the inner ring 410 is preferably smaller than that of the outer ring 420, so that the inner ring 410 is in no contact with the heat sink 530 and thus the juncture between the outer ring 420 and the heat sink 530 would not be affected. The stiffener 400 is preferably made of heat-conductive metal such as copper, galvanized iron and aluminum, so as to further enhance the heat dissipation efficiency.

As is clear from the above description, the inner and outer rings 410, 420 of the present stiffener 400 together cover a majority portion of the upper surface 512 of the substrate 510, not a peripheral portion as in the prior art. This efficiently reinforces the strength and rigidity of the substrate 510 of the present semiconductor package 500, and thus warpage of the substrate 510 is prevented.

Referring to FIG. 6, a stiffener 600 for use with a reinforced semiconductor package in accordance with a second embodiment of the present invention is similar to that of the first embodiment. The stiffener 600 is different from the stiffener 400 of the first embodiment in that the stiffener 600 further comprises, besides an inner ring 410 and an outer ring 420 similar to those of the first embodiment, a side portion 640 downwardly extending from the outer perimeter of the outer ring 420, and a lower portion 650 horizontally and inwardly extending from a bottom section 642 of the side portion 640 to form a ring shape.

Also referring to FIG. 7, a reinforced semiconductor package 700 in accordance with the second embodiment of the present invention embodying the stiffener 600 shown in FIG. 6 is illustrated in cross section. The reinforced semiconductor package 700 is similar to that of the first embodiment, and also comprises a substrate 510, a semiconductor chip 520 bonded to an upper surface 512 of the substrate 510, and a heat sink 530. Both the inner ring 410 and the outer ring 420 of the stiffener 600 are also disposed on the upper surface 512 of the substrate 510. The inner ring 410 also accommodates and surrounds the semiconductor chip 520. The heat sink 530 is also positioned on the semiconductor chip 520 and is adhered to an upper surface of the outer ring 420 of the stiffener 600. The difference is that side surfaces 514 of the substrate 510 are further covered by the additional side portion 640 of the stiffener 600, and at least a portion of a lower surface 516 of the substrate 510 is further covered by the additional lower portion 650 of the stiffener 600.

From the above description, it can be seen that, in the second embodiment of the present invention, a majority portion, not a peripheral portion, of the upper surface 512 of the substrate 510 is also covered by the inner and outer rings 410, 420 of the stiffener 600. Further, the side portion 640 of the stiffener 600 covers the side surfaces 514 of the substrate 510, and the lower portion 650 of the stiffener 600 covers at least a portion of the lower surface 516 of the substrate 510. This improved configuration of the present stiffener 600 sufficiently reinforces the strength and rigidity of the substrate 510 of the present semiconductor package 700, and thus warpage of the substrate 510 is eliminated. Similarly, the stiffener 600 is preferably made of heat-conductive metal such as copper, galvanized iron and aluminum, so as to further enhance the heat dissipation efficiency.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the fill extent indicated by the broad general meaning of the terms in which the appended claims are expressed.

What is claimed is:

1. A stiffener for reinforcing a semiconductor package, the semiconductor package having a substrate and a semiconductor chip, the substrate having opposite upper and lower surfaces and a plurality of side surfaces, the semiconductor chip being disposed on the upper surface of the substrate, the stiffener comprising:
an inner ring;
an outer ring surrounding the inner ring; and
at least one tie bar connecting the inner ring with the outer ring;
wherein the inner ring and the outer ring cover a majority portion of the upper surface of the substrate of the semiconductor package, and the inner ring surrounds the semiconductor chip.

2. The stiffener as claimed in claim 1, wherein both the inner ring and the outer ring are rectangular.

3. The stiffener as claimed in claim 2, wherein the stiffener comprises at least four tie bars.

4. The stiffener as claimed in claim 1, wherein the inner ring has a thickness smaller than a thickness of the outer ring.

5. The stiffener as claimed in claim 1, wherein the stiffener is made of metal.

6. The stiffener as claimed in claim 1, wherein the stiffener is made of a material selected from the group consisting of copper, galvanized iron, and aluminum.

7. The stiffener as claimed in claim 1, further comprising a side portion downwardly extending from an outer perimeter of the outer ring and covering the plurality of side surfaces of the substrate.

8. The stiffener as claimed in claim 7, further comprising a lower portion inwardly extending from a bottom section of the side portion and covering at least a portion of the lower surface of the substrate.

9. The stiffener as claimed in claim 8, wherein the lower portion is formed as a ring.

10. A reinforced semiconductor package, comprising:
a substrate having an upper surface;
a semiconductor chip disposed on the upper surface of the substrate;
a stiffener comprising:
an inner ring disposed on the upper surface of the substrate and surrounding the semiconductor chip,
an outer ring disposed on the upper surface of the substrate and surrounding the inner ring, and
at least one tie bar connecting the inner ring with the outer ring; and
a heat sink positioned on the semiconductor chip and the outer ring of the stiffener.

11. The reinforced semiconductor package as claimed in claim 10, wherein both the inner ring and the outer ring of the stiffener are rectangular.

12. The reinforced semiconductor package as claimed in claim 11, wherein the stiffener comprises at least four tie bars connecting the inner ring with the outer ring.

13. The reinforced semiconductor package as claimed in claim 10, wherein the inner ring has a thickness smaller than a thickness of the outer ring.

14. The reinforced semiconductor package as claimed in claim 10, wherein the stiffener is made of metal.

15. The reinforced semiconductor package as claimed in claim 10, wherein the stiffener is made of a material selected from the group consisting of copper, galvanized iron, and aluminum.

16. A reinforced semiconductor package, comprising:
a substrate having opposite upper and lower surfaces and a plurality of side surfaces;
a semiconductor chip disposed on the upper surface of the substrate;
a stiffener comprising:
an inner ring disposed on the upper surface of the substrate and surrounding the semiconductor chip,
an outer ring disposed on the upper surface of the substrate and surrounding the inner ring,
at least one tie bar connecting the inner ring with the outer ring,
a side portion connected with the outer ring and engaging with the plurality of side surfaces of the substrate, and
a lower portion connected with the side portion and engaging with the lower surface of the substrate; and
a heat sink positioned on the semiconductor chip and the outer ring of the stiffener.

17. The reinforced semiconductor package as claimed in claim 16, wherein both the inner ring and the outer ring of the stiffener are rectangular.

18. The reinforced semiconductor package as claimed in claim 17, wherein the stiffener comprises at least four tie bars connecting the inner ring with the outer ring.

19. The reinforced semiconductor package as claimed in claim 16, wherein the inner ring has a thickness smaller than a thickness of the outer ring.

20. The reinforced semiconductor package as claimed in claim 16, wherein the stiffener is made of metal.

21. The reinforced semiconductor package as claimed in claim 16, wherein the stiffener is made of a material selected from the group consisting of copper, galvanized iron, and aluminum.

22. The reinforced semiconductor package as claimed in claim 16, wherein the lower portion of the stiffener is formed as a ring.
